(19) United States
(12) Patent Application Publication
(10) Pub. No.: US 2015/0171287 A1
(43) Pub. Date: Jun. 18, 2015

(54) RESIN SHEET LAMINATE AND PROCESS FOR PRODUCING SEMICONDUCTOR LIGHT-EMITTING ELEMENT USING SAME

(71) Applicant: Toray Industries, Inc., Chuo-ku, Tokyo (JP)

(72) Inventors: Nobuo Matsumura, Otsu-shi (JP); Yutaka Ishida, Otsu-shi (JP); Tesuya Goto, Otsu-shi (JP)

(73) Assignee: Toray Industrieis, Inc., Chuo-ku, Tokyo (JP)

(21) Appl. No.: 14/407,307

(22) PCT Filed: Jun. 13, 2013
(86) PCT No.: PCT/JP2013/066357

§ 371 Date: Dec. 11, 2014

(30) Foreign Application Priority Data
Jun. 28, 2012 (JP) 2012-145161

(51) Int. Cl. H01L 33/50; H01L 33/54

(52) U.S. Cl. CPC H01L 33/507; H01L 33/54; H01L 2933/0041; H01L 2933/005

(57) ABSTRACT

Provided is a resin sheet laminate which is provided with a phosphor-containing resin layer on a base material, characterized in that: the Phosphor-containing resin layer has a plurality of subdivisions; the base material has lengthwise and widthwise directions; and a plurality of the subdivisions are repeatedly arranged in the lengthwise direction of the base material in a line, and the resin sheet laminate can improve the uniformity of color or luminance of a semiconductor light-emitting element having a phosphor-containing resin layer bonded thereon, the ease of production of the element, the degree of freedom in design thereof, and so on.

### CROSS REFERENCE TO RELATED APPLICATIONS

This is the U.S. National Phase application of PCT/JP2013/066357, filed Jun. 13, 2013, which claims priority to Japanese Patent Application No. 2012-145161, filed Jun. 28, 2012, the disclosures of each of these applications being incorporated herein by reference in their entireties for all purposes.

### FIELD OF THE INVENTION

The present invention relates to a resin sheet laminate including a base material and a phosphor-containing resin sheet provided on the base material. More particularly, the present invention relates to a resin sheet laminate in which a base material has lengthwise and widthwise directions, and subdivisions of a fluorescent material-containing resin sheet layer for converting the emission wavelength of a semiconductor light-emitting element are repeatedly arranged in the lengthwise direction of the base material in a line.

### BACKGROUND OF THE INVENTION

The market of a light emitting diode (LED) is rapidly expanding for a backlight of a liquid crystal display (LCD) and for general lighting in addition to lighting in automotive applications such as headlight because of its low power consumption, long life and design with a significant improvement in luminance efficiency as the background.

An emission color of an LED is limited since an emission spectrum of the LED depends on a semiconductor material for forming the semiconductor light-emitting element. Therefore, in order to obtain LCD backlight or white light for general lighting by using an LED, it is necessary that a phosphor suitable for an LED chip is arranged on the semiconductor light-emitting element to convert the emission wavelength. Specifically, a method of arranging a yellow phosphor on a semiconductor light-emitting element that emits blue light, a method of arranging a red phosphor and a green phosphor on a semiconductor light-emitting element that emits blue light, and a method of arranging a red phosphor, a green phosphor and a blue phosphor on a semiconductor light-emitting element that emits ultraviolet light are proposed. Among these methods, the method of arranging a yellow phosphor on a blue LED, and the method of arranging a red phosphor and a green phosphor on a blue LED are currently most widely employed from the viewpoint of luminance efficiency and cost of the semiconductor light-emitting element.

A method of dispersing a phosphor in a liquid resin for encapsulating a semiconductor light-emitting element is proposed as a specific method of arranging a phosphor on the semiconductor light-emitting element (e.g., refer to Patent Literatures 1 and 2). However, when the phosphor is nonuniformly dispersed in the liquid resin, color deviation arises among semiconductor light-emitting elements. Further, since a constant quantity is hardly maintained when supplying a liquid resin on a semiconductor light-emitting element individually and thickness variation of the liquid resin is easily produced during curing the resin, it is difficult to maintain the amount of the phosphor arranged on the semiconductor light-emitting element constant.

Thus, a method of using a sheet-like resin layer in which a fluorescent material is uniformly distributed in advance is proposed (e.g., Patent Literatures 3 and 4). Constant phosphors can be arranged on each semiconductor light-emitting element and the quality of the LED can be improved by cutting the resulting sheet into small pieces and bonding them to a semiconductor light-emitting element.

[Patent Literatures]

[PTL 1] JP 5-152609 A

[PTL 2] JP 7-99345 A

[PTL 3] JP 4146406 B1

[PTL 4] JP 2000-156528 A

### SUMMARY OF THE INVENTION

It is necessary to supply LEDs having small color deviation of emission color stably for widely adapting the LEDs to general lighting uses in place of incandescent bulbs or fluorescent lamps. As described above, the method in which a fluorescent material is uniformly dispersed in a resin in advance and the resin is formed into a sheet having a uniform thickness is excellent as a method of suppressing color deviation. However, this method has a problem that a step of cutting a sheet and a step of bonding the sheet to a semiconductor light-emitting element by use of an adhesive that are described below are added to the production process of a light-emitting element using the LED to make the production process complicated, resulting in low throughput and an increase in production cost.

When the phosphor-containing resin is formed into a sheet in advance, the sheet has to be arranged on individual semiconductor light-emitting elements. For example, when the phosphor-containing resin sheet has been cut into a size suitable to be arranged on individual semiconductor light-emitting elements in advance, it is difficult to handle the phosphor-containing sheet cut into pieces of about 1 mm. Further, the work of bonding the individual pieces to the semiconductor light-emitting element one by one by using an adhesive requires accuracy, and it is difficult to satisfy both of the production speed and accuracy simultaneously.

As another method, there is a method in which the phosphor-containing resin sheet in the form of a continuous sheet is bonded to the LED without cutting the sheet into individual pieces. In this case, there are two cases, that is, a case where an individual semiconductor light-emitting element is bonded to a sheet-like phosphor-containing resin layer and a case where the LED in the form of a wafer before divided into individual pieces is collectively bonded to the phosphor-containing resin layer. However, in either method, a method of cutting the phosphor-containing resin sheet after bonding it to the semiconductor light-emitting element is limited. Particularly, in the latter case, it is difficult to cut the phosphor-containing resin sheet concurrently with cutting of a wafer of the LED. Further, when the phosphor resin sheet is cut after bonding to the semiconductor light-emitting element, the shape of the cut piece is limited to a shape following the shape of the semiconductor light-emitting element or a shape larger than that of the semiconductor light-emitting element. Accordingly, when it is desired to cover a part of the semiconductor light-emitting element with the phosphor-containing resin layer and expose a different part of the semiconductor light-emitting element, for example, for the case of forming a lead out of an electrode on the semiconductor light-emitting element, it is difficult to eliminate only the part of the phosphor-containing resin layer corresponding to the different part.

The present inventors made earnest investigations concerning the uniformity of color or luminance of a semiconductor light-emitting element having a phosphor-containing resin sheet bonded thereon, the ease of production of the element, the degree of freedom in design thereof, and so on, and consequently the present inventors found that in order to improve all these characteristics, a machining shape and arrangement of the phosphor-containing resin sheet on a base material are very important.

That is, the present invention pertains to a resin sheet laminate having a resin sheet containing a phosphor and a resin on or over a long base material, wherein subdivisions of the resin sheet are repeatedly arranged in a lengthwise direction of the long base material.

In accordance with the present invention, an LED having uniform luminance and color can be produced by an easy process.

### BRIEF DESCRIPTION OF DRAWINGS

FIG. 1 shows plan views showing an example of a resin sheet laminate of the present invention.

FIG. 2 shows plan views showing another example of a resin sheet laminate of the present invention.

FIG. 3 shows plan views showing another example of a resin sheet laminate of the present invention.

FIG. 4 shows sectional views showing an example of a resin sheet laminate of the present invention.

FIG. 5 shows process side views showing an example of a method for adhering a phosphor-containing resin sheet in the present invention to a semiconductor light-emitting element.

FIG. 6 shows process side views showing an example of a method for adhering a phosphor-containing resin sheet in the present invention to a semiconductor light-emitting element.

FIG. 7 is a side view showing an example of a method for adhering a phosphor-containing resin sheet in the present invention to a semiconductor light-emitting element.

FIG. 8A shows process side views showing an example of a method for adhering a phosphor-containing resin sheet in the present invention to a semiconductor light-emitting element.

FIG. 8B shows process side views showing an example of a method for adhering a phosphor-containing resin sheet in the present invention to a semiconductor light-emitting element.

FIG. 9 shows side views showing an example of a method for adhering a phosphor-containing resin sheet in the present invention to a semiconductor light-emitting element.

FIG. 10 is a side view showing an example of a method for adhering a phosphor-containing resin sheet in the present invention to a semiconductor light-emitting element.

FIG. 11 is a side view showing an example of a method for adhering a phosphor-containing resin sheet in the present invention to a semiconductor light-emitting element.

FIG. 12 shows side views showing an example of a method for adhering a phosphor-containing resin sheet in the present invention to a semiconductor light-emitting element.

FIG. 13 is a side view showing an example of a method for adhering a phosphor-containing resin sheet in the present invention to a semiconductor light-emitting element.

FIG. 14 is a side view showing an example of a method for adhering a phosphor-containing resin sheet in the present invention to a semiconductor light-emitting element.

FIG. 15 shows process side views showing an example of a method for adhering a phosphor-containing resin sheet in the present invention to a semiconductor light-emitting element.

### DETAILED DESCRIPTION OF EMBODIMENTS OF THE INVENTION

The present invention pertains to a resin sheet laminate having a resin sheet containing a phosphor and a resin on or over a long base material, wherein subdivisions of the resin sheet are repeatedly arranged in the lengthwise direction of the long base material. Hereinafter, the resin sheet containing a phosphor and a resin is referred to as a “phosphor-containing resin sheet.”

The subdivisions of the phosphor-containing resin sheet can be arranged in a desired shape, dimension and number depending on the objective. On the other hand, the base material for supporting the subdivisions of the phosphor-containing resin sheet is monolithic throughout a plurality of subdivisions of the phosphor-containing resin sheet, and the subdivisions of the phosphor-containing resin sheet are not fragmented individually.

In the resin sheet laminate of the present invention, since subdivisions of the resin sheet in which the phosphor is uniformly dispersed are formed in a desired thickness and in a desired shape in advance, a phosphor-containing resin layer having a uniform thickness and uniform composition can be formed on each LED by using the resin sheet laminate. Further, while the subdivisions of the phosphor-containing resin sheet are divided into a desired shape in advance, these subdivisions are repeatedly arranged in the lengthwise direction of the base material. Therefore, the resin sheet can be easily handled and can be bonded to the semiconductor light-emitting element by a simple step. Accordingly, LEDs which are uniform in luminance and color can be produced by an easy process by using the resin sheet laminate of the present invention.

Thus, the base material in the resin sheet laminate of the present invention is preferably continuous and has lengthwise and widthwise directions. Here, in the present specification, the phrase “the base material is continuous” refers to a state in which the base material is not fully separated. That is, this state includes not only the case where no cut is made in the base material, but also the case where the base material has a cut not penetrating the base material in a direction of thickness and the case where the base material has a cut partially penetrating the base material but retains a monolithic and continuous shape as a whole.

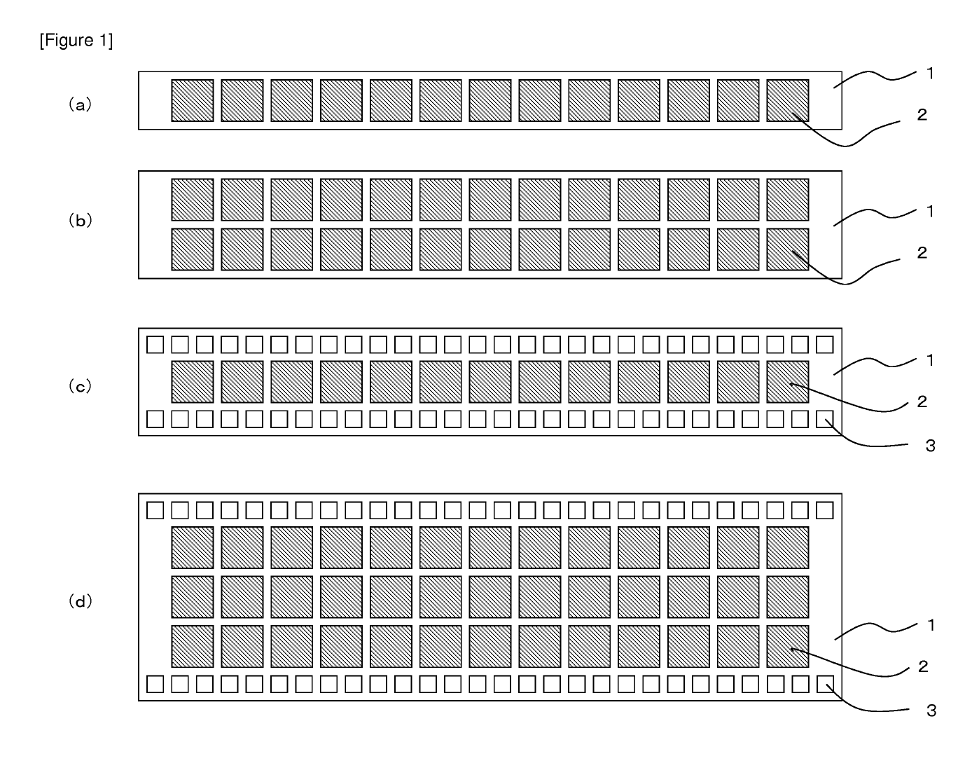

The constitution of the resin sheet laminate of an embodiment of the present invention will be described with reference to FIGS. 1 to 4. These are merely examples, and the resin sheet laminate of the present invention is not limited to these examples.

FIG. 1(a) is an example of a constitution of a resin sheet laminate of the present invention. A large number of subdivisions of a phosphor-containing resin sheet 2 formed into a predetermined shape are laminated in a lengthwise direction in a line on a continuous base material 1 which has lengthwise and widthwise directions.

FIG. 1(b) is another example of a constitution of a resin sheet laminate of the present invention. A large number of subdivisions of a phosphor-containing resin sheet 2 formed into a predetermined shape are laminated in a lengthwise direction in two lines on a continuous base material 1 which has lengthwise and widthwise directions. As described above, the number of lines of the phosphor-containing resin sheet 2 does not need to be one, and the phosphor-containing resin sheet 2 may be formed in a plurality of lines as required.

FIG. 1(c) is another example of a constitution of a resin sheet laminate of the present invention. A large number of subdivisions of a phosphor-containing resin sheet 2 formed into a predetermined shape are laminated in a lengthwise direction in one line on a continuous base material 1 which has lengthwise and widthwise directions, and holes (conveyance holes 3) used in conveying the resin sheet laminate are holed so as to queue up in a lengthwise direction in an area of the base material 1 where the phosphor-containing resin sheet 2 is absent. In a step of bonding the phosphor-containing resin sheet to an emission surface of the semiconductor light-emitting element by using the resin sheet laminate of the present invention, when alignment is performed while carrying the resin sheet laminate in a lengthwise direction, precise alignment can be performed by using such conveyance holes 3 and carrying the resin sheet laminate by a gear type carrying apparatus.

FIG. 1(d) is another example of a constitution of a resin sheet laminate of the present invention. A large number of subdivisions of a phosphor-containing resin sheet 2 formed into a predetermined shape are laminated in a lengthwise direction in three lines on a continuous base material 1 which has lengthwise and widthwise directions, and conveyance holes 3 are holed so as to be in line in a lengthwise direction in an area of the base material 1 where the phosphor-containing resin sheet 2 is absent. As described above, a plurality of lines of the subdivisions of the phosphor-containing resin sheet can be formed also when the conveyance holes 3 are formed in the base material 1.

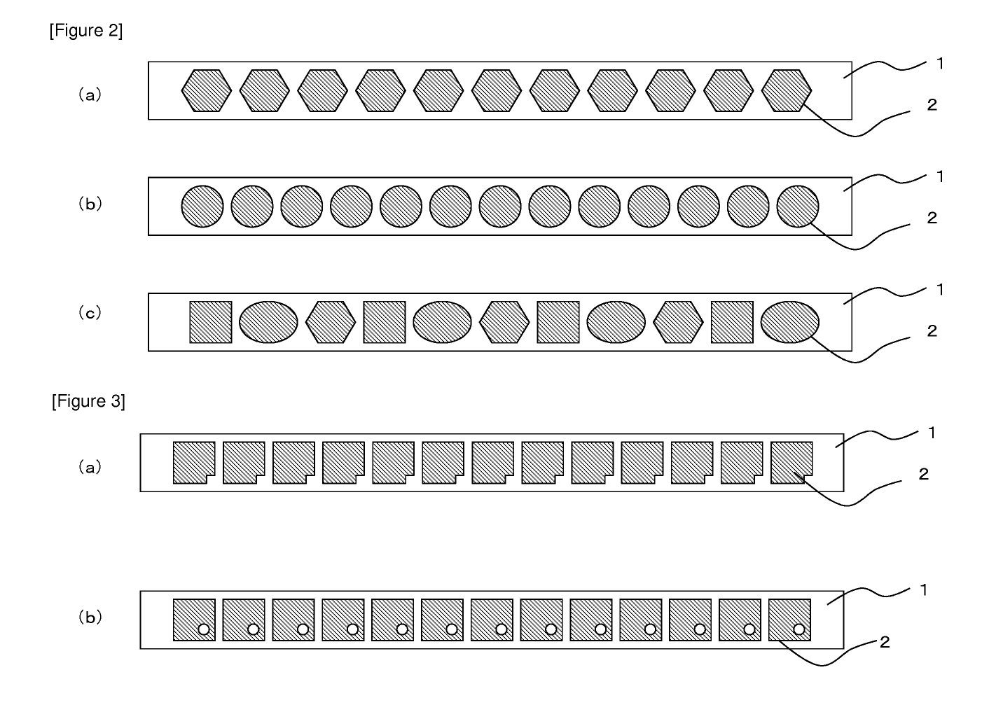

Further, subdivisions of the phosphor-containing resin sheet 2 arrayed on the base material 1 do not have to be rectangular, and the subdivisions may be hexagonal as shown in FIG. 2(a) or polygonal otherwise, or may be circular as shown in FIG. 2(b). Further, as shown in FIG. 2(c), different shapes such as a rectangle, an ellipse and a hexagon may be regularly or irregularly arrayed. In principle, the subdivision of the phosphor-containing resin sheet is formed into a shape conforming to the shape of the emission surface of the semiconductor light-emitting element. When the phosphor-containing resin sheet is adhered to a semiconductor light-emitting element having an electrode on an emission surface side, the subdivision of the phosphor-containing resin sheet may be partially cut away as shown in FIG. 3(a), or may be holed as shown in FIG. 3(b) in order to bond the phosphor-containing resin sheet so as to avoid an electrode joint portion.

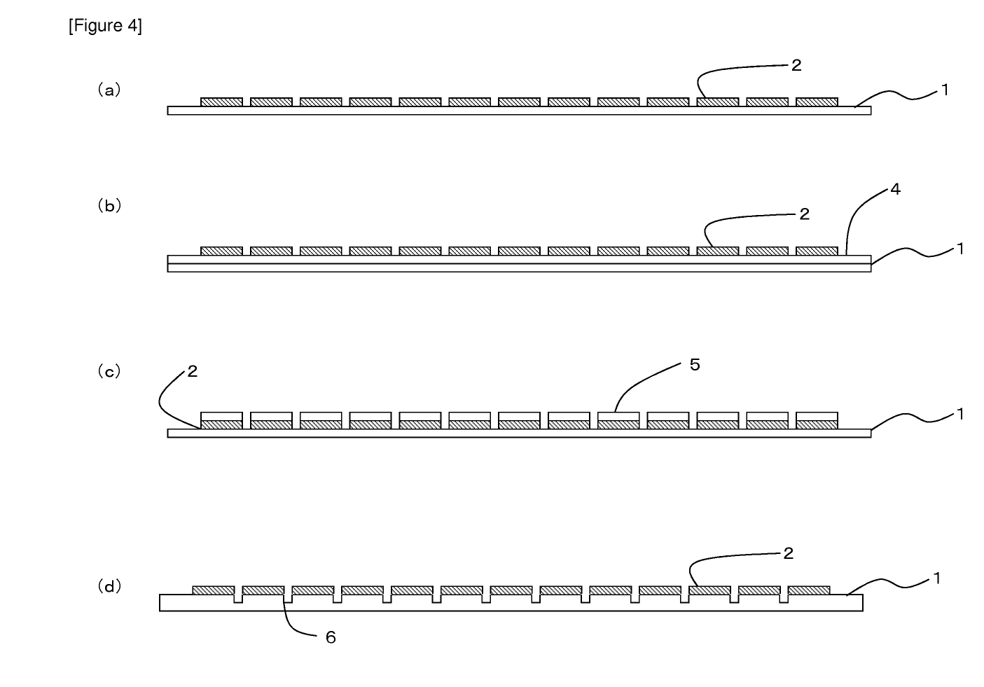

FIG. 4(a) is a sectional view showing an example of a constitution of a resin sheet laminate of the present invention. The subdivisions of the phosphor-containing resin sheet 2 are directly arrayed on the base material 1 in contact with the base material 1. FIG. 4(b) is a sectional view showing another example of a constitution of a resin sheet laminate of the present invention, in which a release layer 4 is present between the base material 1 and the phosphor-containing resin sheet 2. The release layer 4 is formed for making an adhesive power between the base material 1 and the phosphor-containing resin sheet 2 optimum for the process, and a publicly known release layer can be used. FIG. 4(c) is a sectional view showing another example of a constitution of a resin sheet laminate of the present invention. The resin sheet laminate has an adhesion layer 5 on the surface of the phosphor-containing resin sheet 2 opposite to the base material. The adhesion layer 5 is formed for improving an adhesive power between the phosphor-containing resin sheet 2 and the semiconductor light-emitting element and has an adhesion component or a pressure sensitive adhesion component, the so-called adhesive component, in its component. When the phosphor-containing resin sheet 2 itself has an adhesive property or has thermal adhesiveness, the adhesion layer 5 is unnecessary.

The phrase that “the phosphor-containing resin sheet has an adhesive property” referred to herein means that the phosphor-containing resin sheet itself has a capability of adhering to a semiconductor light-emitting element. Specific examples thereof include (1) a phosphor-containing resin sheet whose resin component has a pressure sensitive adhesion component, the so-called adhesive component, and which adheres to a semiconductor light-emitting element by adhesion and (2) a phosphor-containing resin sheet whose resin component has a component to be cured at normal temperature or by heating, and which adheres to a semiconductor light-emitting element by a curing reaction.

Further, the phrase “the phosphor-containing resin component has thermal adhesiveness” referred to herein refers to a phosphor-containing resin sheet whose resin component has a thermoplastic component whose elastic modulus is significantly decreased by an increase in temperature, and which is brought into intimate contact with a semiconductor light-emitting element by heating and bonding of the resin sheet, and adheres to the semiconductor light-emitting element through an increase in the elastic modulus and fixation of the resin by cooling of the resin sheet to room temperature. Further, the phosphor-containing resin sheet may be a phosphor-containing resin sheet whose resin component combines curability and thermal adhesiveness, and which is brought into intimate contact with a semiconductor light-emitting element through a decrease in elastic modulus by heating, and fixed onto the semiconductor light-emitting element through curing of the resin by further heating.

While the adhesion layer 5 may contain a phosphor, it is preferred that the adhesion layer 5 does not contain a phosphor or contains a phosphor in a lower concentration than in the phosphor-containing resin sheet 2 since an adhesive power is usually reduced in the case where the adhesion layer 5 contains particles at high concentration. It is also possible to provide both of the release layer 4 shown in FIG. 4(b) and the adhesion layer 5 shown in FIG. 4(c).

FIG. 4(d) is a sectional view showing another example of a constitution of a resin sheet laminate of the present invention. A phosphor-containing resin sheet 2 is arrayed on a base material 1, and the base material 1 has a concave portion at approximately the same position as that of a boundary between subdivisions of the phosphor-containing resin sheet 2. At this time, a part of the concave portion of the base material may be a break penetrating the base material as long as the base material is monolithic. Such a constitution of the resin sheet laminate is preferred since when only one subdivision of the phosphor-containing resin sheet 2 is peeled off, an adjacent subdivision is not peeled off. The reason for this is as follows: if the base material does not have such a concave portion in peeling the subdivision of the phosphor-containing resin sheet 2 divided into the subdivisions from the base material one by one, there is a fear that an adjacent subdivision is simultaneously peeled off when the subdivision is very small; however, when the concave portion with a depth not penetrating the base material is provided, stress is dispersed and a large peeling force is not exerted on the adjacent subdivision. Such a concave portion of the base material 1 is also applicable to the case of a constitution including a release layer 4 as shown in FIG. 4(b), the case of a constitution including an adhesion layer on the phosphor-containing resin sheet 2 as shown in FIG. 4(c), or the case of a constitution including a release layer 4 and an adhesion layer 5 as shown in FIG. 4(b) and FIG. 4(c).

(Base Material)

As the long base material 1, publicly known metal, film, glass, ceramic, paper or the like can be used. Specific examples of the base material include plates or foils of metals such as aluminum (including an aluminum alloy), zinc, copper and iron; resin films such as cellulose acetate, polyethylene terephthalate (PET), polyethylene, polyester, polyamide, polyimide, polyphenylenesulfide, polysulfone, polyethersulfone, polystyrene, polypropylene, polycarbonate, polyvinyl acetal and aramid; and paper having plastics (polyethylene, polypropylene, polystyrene, etc.) laminated thereon or paper coated with such plastics, paper or films of plastics having the above-mentioned metals laminated or deposited thereon. Among them, as the base material, flexible film-like materials are preferred from the viewpoint of adhesion in bonding the phosphor-containing resin sheet 2 to the semiconductor light-emitting element, and films having high strength are preferred in order to avoid a fear of breaking in handling a film-like base material. A resin film is preferred from the viewpoints of the above-mentioned required characteristics and economic efficiency, and among resin films, a PET film is particularly preferred. When punching of conveyance holes or the like is performed, a polyphenylenesulfide film is more suitable from the viewpoint of the ability of the film to be punched by machining. When an elevated temperature of 200° C. or more is required for curing a resin, a polyimide film is more preferred from the viewpoint of heat resistance. Further, when the base material is a metal plate, the plate surface may be subjected to chromium- or nickel-plating or ceramic treatment.

The thickness of the base material is not particularly limited, but the lower limit of the thickness is preferably 25 μm or more, and more preferably 50 μm or more. Also, the upper limit of the thickness is preferably 5000 μm or less, and more preferably 3000 μm or less.

A component of the phosphor-containing resin sheet 2 is not particularly limited as long as it contains primarily a resin and a phosphor, and various components can be used. Other components may be contained in the component as required.

(Phosphor)

The phosphor absorbs light emitted from the semiconductor light-emitting element, converts the wavelength of the light, and emits light having a different wavelength from that of the light of the semiconductor light-emitting element. Thereby, a part of light emitted from the semiconductor light-emitting element is mixed with a part of light emitted from the phosphor to give a light emitting device of multiple colors including a white color. Specifically, by optically combining a blue semiconductor light-emitting element with a phosphor which emits light of yellowish emission colors by light from the semiconductor light emitting device, it is possible to emit white light by using a single semiconductor light-emitting element.

The phosphors described above include various phosphors such as a phosphor emitting green light, a phosphor emitting blue light, a phosphor emitting yellow light, and a phosphor emitting red light. Specific examples of the phosphor used in the present invention include publicly known phosphors such as inorganic phosphors, organic phosphors, fluorescent pigments and fluorescent dyes. Examples of the organic phosphors include an allylsulfoamide-melamineformaldehyde cocondensation dye and a perylene phosphor, and a perylene phosphor is preferably used since it can be used for a long term. Examples of the fluorescent material particularly preferably used in the present invention include inorganic phosphors. Hereinafter, examples of the inorganic phosphor that can be used in the present invention will be described.

Examples of a phosphor emitting green light include SrAl₂O₄:Eu, Y₂SiO₅:Ce, MgAl₁₁O19:Ce, Tb, Sr₇Al₁₂O₂₅:Eu, and (at least one of Mg, Ca, Sr and Ba)Ga₂S₄:Eu.

Examples of a phosphor emitting blue light include Sr₅(PO₄)₃Cl:Eu, (SrCaBa)₅(PO₄)₃Cl:Eu, (BaCa)₅(PO₄)₃Cl:Eu, (at least one of Mg, Ca, Sr and Ba)₂B₅O₉Cl:Eu, Mn, (at least one of Mg, Ca, Sr and Ba) (PO₄)₆Cl₂:Eu, and Mn.

Examples of a phosphor emitting green-yellow light include an yttrium-aluminum oxide phosphor activated with at least cerium, an yttrium-gadolinium-aluminum oxide phosphor activated with at least cerium, an yttrium-aluminum-garnet oxide phosphor activated with at least cerium, and an yttrium-gallium-aluminum oxide phosphor activated with at least cerium (the so-called YAG-based phosphors). Specifically, Ln₃M₅O₁₂:R (Ln is at least one selected from among Y, Gd and La, M includes at least one of Al and Ca, and R is a lanthanoid-based phosphor) and (Y₁₋ₓGaₓ)₃(Al_{1-y}Ga_{y})₅O₁₂:R (R is at least one selected from among Ce, Tb, Pr, Sm, Eu, Dy and Ho, and 0<x<0.5, 0<y<0.5) can be used.

Examples of a phosphor emitting red light include Y₂O₂S:Eu, La₂O₂S:Eu, Y₂O₃:Eu, and Gd₂O₂S:Eu.

Further, examples of a phosphor emitting light compatible with a blue LED which is currently mainstream include YAG-based phosphors such as Y₃(Al,Ga)₅O₁₂:Ce, (Y,Gd)₃Al₅O₁₂:Ce, Lu₃Al₅O₁₂:Ce and Y₃Al₅O₁₂:Ce; TAG-based phosphors such as Tb₃Al₅O₁₂:Ce; silicate-based phosphors such as a (Ba,Sr)₂SiO₄:Eu phosphor, a Ca₃Sc₂Si₃O₁₂:Ce phosphor and a (Sr,Ba,Mg)₂SiO₄:Eu phosphor; nitride-based phosphors such as (Ca,Sr)₂Si₅N₈:Eu, (Ca,Sr)AlSiN₃:Eu and CaSiAlN₃:Eu, oxynitride-based phosphors such as Cax (Si,Al)₁₂(O,N)₁₆:Eu; and a (Ba,Sr,Ca)Si₂O₂N₂:Eu phosphor, a Ca₈MgSi₄O₁₆Cl₂:Eu phosphor, SrAl₂O₄:Eu, and Sr₄Al₁₄O₂₅:Eu.

Among these phosphors, YAG-based phosphors, TAG-based phosphors and silicate-based phosphors are preferably used from the viewpoints of luminance efficiency and luminance.

Publicly known phosphors other than the above-mentioned phosphors can be used according to uses or a desired emission color.

The particle size of the phosphor is not particularly limited, but particles with a D50 of 0.05 μm or more are preferred, and particles with a D50 of 3 μm or more are more preferred. Further, particles with a D50 of 30 μm or less are preferred, and particles with a D50 of 20 μm or less are more preferred. Herein, D50 refers to a particle diameter at which the cumulative percentage of particles passing from the small particle-size side in the volume-based particle size distribution obtained by a laser diffraction/scattering particle size distribution measurement method reaches 50%. When D50 is within the above-mentioned range, dispersibility of the phosphor in the sheet is good, and stable emission is achieved.

(Resin)

The resin used in the present invention is a resin for containing a phosphor therein, and eventually forms a sheet. Accordingly, any resin may be employed as long as it allows the phosphor to be uniformly dispersed therein and can forma sheet. Specific examples of the resin include a silicone resin, an epoxy resin, a polyallylate resin, a PET-modified polyallylate resin, a polycarbonate resin, a cyclic olefin, a polyethylene terephthalate resin, a polymethyl methacrylate resin, a polypropylene resin, modified acrylic, a polystyrene resin, and an acrylonitrile-styrene copolymer resin. In the present invention, a silicone resin or an epoxy resin is preferably used from the viewpoint of transparency. Furthermore, a silicone resin is particularly preferably used from the viewpoint of heat resistance.

As the silicone resin used in the present invention, a curable silicone rubber is preferred. Any liquid form of one-component liquid form and two-component liquid form (three-component liquid form) may be employed. Types of the curable silicone rubber include a type that causes a condensation reaction by moisture in the air or a catalyst, which includes a dealcoholization type, a deoximation type, an acetic acid elimination type, and a hydroxylamine elimination type. Examples of a type that causes a hydrosilylation reaction by a catalyst include an addition reaction type. Any of these types of curable silicone rubbers may be used. Particularly, the addition reaction type silicone rubber is more preferred in that a by-product associated with a curing reaction is not produced, shrinkage by curing is small, and curing can be easily accelerated by heating.

The addition reaction type silicone rubber is formed by a hydrosilylation reaction of a compound containing an alkenyl group coupled with a silicon atom with a compound containing a hydrogen atom coupled with a silicon atom, for example. Examples of the materials described above include compounds formed by a hydrosilylation reaction of compounds containing an alkenyl group coupled with a silicon atom, such as vinyltrimethoxysilane, vinyltriethoxysilane, allyltrimethoxysilane, propenyltrimethoxysilane, norbornenyltrimethoxysilane and (octenyl)trimethoxysilane with compounds containing a hydrogen atom coupled with a silicon atom, such as methylhydrogenpolysiloxane, dimethylpolysiloxane-CO-methylhydrogenpolysiloxane, ethylhydrogenpolysiloxane and methylhydrogenpolysiloxane-CO-methylphenylpolysiloxane. Further, as other materials, for example, publicly known materials described in JP 2010-159411 A can be utilized.

Further, as commercialized products, it is also possible to use general-use silicone encapsulation materials for LEDs. Specific examples of such encapsulation materials include OE-6630 A/B and OE-6336 A/B manufactured by Dow Corning Toray Co., Ltd. and SCR-1012 A/B and SCR-1016 A/B manufactured by Shin-Etsu Chemical Co., Ltd.

Further, when the resin has thermal adhesiveness, the production process is simplified since it is not necessary to additionally provide an adhesion layer described later on the phosphor-containing resin sheet. A resin which is an addition reaction type silicone rubber and has thermal adhesiveness is the most preferred from the viewpoints of optical characteristics and durability.

(Other Components)

It is also possible to add a dispersant or a leveling agent for stabilizing a coating film as an additive, or an adhesion aid such as a silane coupling agent as a modifier of a sheet surface. Also, inorganic particles such as silicone fine particles can be added as an anti-settling agent for a phosphor.

The silicone fine particles for anti-settling of the phosphor preferably has an average particle size (D50) of 0.01 μm or more and less than 5 μm. When the average particle size (D50) is 0.01 μm or more, the silicone fine particles can be easily produced and easily dispersed in the phosphor-containing resin sheet. When the average particle size (D50) is less than 5 μm, the transmittance of the phosphor-containing resin sheet is not adversely affected.

(Phosphor Content)

The content of the phosphor is preferably 53% by weight or more, and more preferably 60% by weight or more of the total weight of the phosphor-containing resin sheet. By adjusting the content of the phosphor in the phosphor-containing resin sheet to the above-mentioned range, light resistance of the phosphor-containing resin sheet can be enhanced. In addition, the upper limit of the phosphor content is not particularly limited, but the content is preferably 95% by weight or less, more preferably 90% by weight or less, further preferably 85% by weight or less, and particularly preferably 80% by weight or less of the total weight of the phosphor-containing resin sheet from the viewpoint of ease of producing a sheet excellent in workability.

(Thickness of Phosphor-Containing Resin Sheet)

The thickness of the phosphor-containing resin sheet is preferably 200 μm or less, and more preferably 100 μm or less from the viewpoint of improving heat resistance of the phosphor-containing resin sheet.

The thickness of the sheet in the present invention refers to a thickness (average thickness) measured according to JIS K 7130 (1999) “Plastics—Film and sheeting—Determination of thickness by mechanical scanning (A).”

The environment of the LED is an environment in which a large amount of heat is generated in a small space, and particularly in the case of a high power LED, heat generation is remarkable. The temperature of the phosphor is raised by such heat generation and hence the luminance of the LED is reduced. Accordingly, it is important how efficiently the generated heat is dissipated. In the present invention, a sheet having excellent heat resistance can be attained by setting the thickness of the sheet to the above-mentioned range. Further, when the sheet shows variations in the thickness, there are differences in the amount of the phosphor among the semiconductor light-emitting elements, and consequently there are variations in emission spectrum. Accordingly, variations in the thickness of the sheet are preferably within a range of ±5%, more preferably within a range of ±3%, and further preferably within a range of ±1.5%. The variation in the thickness referred to herein is determined by measuring the thickness according to JIS K 7130 (1999) “Plastics—Film and sheeting—Determination of thickness by mechanical scanning (A),” and calculating the variation from the following equation.

More specifically, using measurement conditions of “Determination of thickness by mechanical scanning (A),” the thickness is measured with a commercially available micrometer such as a contact type thickness measurement apparatus, and a difference between the maximum value or the minimum value of the resulting thickness and the average thickness is calculated. The ratio expressed in percentage of the calculated value divided by the average thickness is a thickness variation B (%).

Thickness variation B(%)=(maximum thickness deviation*−average thickness)/average thickness×100

* As the maximum thickness deviation, of the two differences in the thickness between the maximum value and the average value and between the minimum value and the average value, the larger difference is selected.

(Other Constitutions)

The material of the release layer 4 is not particularly limited, and a material commonly used can be used. While a general-purpose release agent includes wax, liquid paraffin, silicone-based release agents, and fluorine-based release agents, as a release agent for a resin, in general, silicone-based release agents or fluorine-based release agents are often used. These release agents can be suitably used also in the present invention. Particularly, silicone-based release agents are suitable because of high mold releasability. The material selection or the application amount to the base material of the release layer 4 is determined depending on required peeling strength. That is, by properly selecting the type and quantity of the release agent, the phosphor-containing resin sheet is not peeled from the base material in machining the sheet into a desired shape, and the phosphor-containing resin sheet can be peeled quickly from the base material when bonding the phosphor-containing resin sheet to the semiconductor light-emitting element. Since the peeling strength varies depending on the composition of the phosphor-containing resin sheet even when the same release agent is used in the same amount, it is desirable to adjust the peeling strength for every phosphor-containing resin sheet to be used in order to obtain a required releasing property.

The material of the adhesion layer 5 is not particularly limited, and examples thereof include common rubber-based, acrylic, urethane-based, and silicone-based adhesive agents. Any material may be used, but a silicone-based adhesive agent is useful as an adhesive agent suitable for heat resistance, an insulating property and transparency.

The thickness of the adhesion layer 5 is preferably 2 μm or more and 200 μm or less. When the thickness of the adhesion layer 5 is 2 μm or more, high adhesive strength can be achieved regardless of the type of the adhesive agent. When the thickness of the adhesion layer is 200 μm or less, the phosphor-containing resin sheet 2 can be machined without causing a failure in tackiness of the adhesion layer 5 in machining the phosphor-containing resin sheet 2 into a desired shape, and an optical loss is not produced after the phosphor-containing resin sheet 2 is bonded to the semiconductor light-emitting element. Further, when it is necessary to embed a structure of the surface of the semiconductor light-emitting element or a protruding object such as a mounting electrode, the adhesion layer 5 having a thickness of 200 μm or less can achieve an adequate ability to embed these structures since these structures usually have a size of 100 μm or less.

A protective film may be provided on the phosphor-containing resin sheet 2. The material of the protective film is not particularly limited, and examples thereof include polyethylene terephthalate (PET), polyethylene, polypropylene, polyvinyl chloride, and cellophane. Further, the protective film may be subjected to releasing treatment by a publicly known release agent such as a silicone-based release agent or a fluorine-based release agent. The protective film can be provided on the adhesion layer 5 when the adhesion layer 5 is present on the phosphor-containing resin sheet 2 as shown in FIG. 4(c).

(Method for Producing Resin Sheet Laminate)

A method for producing a resin sheet laminate of the present invention will be described. These are examples, and the method for producing a resin sheet laminate of the present invention is not limited to these examples.

The phosphor-containing resin sheet 2 is laminated on the base material 1 by a method described later. Then, a photoresist is laminated thereon and patterned to form a corrosion-resistant pattern, and the phosphor-containing resin sheet 2 is etched with a chemical solution which dissolves the phosphor-containing resin sheet 2 by using the corrosion-resistant pattern as a mask to divide the phosphor-containing resin sheet 2 into a desired shape. A commercially available product can be utilized as the photoresist.

Further, in another exemplary method for producing a resin sheet laminate of the present invention, a screen printing plate provided with a pattern formed thereon is overlaid on a base material 1, and a paste formed by dispersing a phosphor in a resin solution is filled into the screen printing plate with a squeegee, printed and dried to form a phosphor-containing resin sheet 2 divided into a predetermined shape. In this method, since a method capable of printing in the form of a pattern such as screen printing is used in order to form a phosphor-containing resin layer 2 on the base material, a desirably patterned phosphor-containing resin sheet 2 can be directly obtained. As the screen printing plate, it is necessary to select a printing plate which is resistant to a solvent contained in the phosphor-containing resin sheet 2. A stainless steel gauze provided with a pattern of a resin with high chemical resistance is preferred.

In still another exemplary method for producing a resin sheet laminate of the present invention, the phosphor-containing resin sheet 2 is formed on the base material 1 by a method described later. Thereafter, the phosphor-containing resin sheet 2 is divided and machined into a desired shape by any machining method of punching by a die, machining by a laser beam and cutting by a blade. When the phosphor-containing resin sheet 2 is divided into subdivisions, it is important that at least a part of the base material is not penetrated so that the base material is in a monolithic state, and cutting by a blade is desirable as a method of not penetrating the base material. Examples of a cutting method by a blade include a method of pushing a simple blade in the phosphor-containing resin sheet to cut the sheet, and a method of cutting the phosphor-containing resin sheet with a rotary blade. As an apparatus for cutting the sheet by the rotary blade, an apparatus called a dicer, which is used for cutting (dicing) a semiconductor substrate into individual chips, can be suitably utilized. When the dicer is used, the width of a dividing line can be precisely controlled by the thickness of the rotary blade or setting of conditions, and therefore higher machining accuracy can be attained than cutting through pushing by a simple blade.

In any method of using a blade, it is possible to avoid cutting the base material while dividing the phosphor-containing resin sheet 2 if highly precise position control of the blade is performed; however, it is actually very difficult to make a cut in a completely constant depth. Therefore, in order to prevent the phosphor-containing resin sheet 2 from being not properly divided when the cutting depth is slightly deviated, the cutting depth is preferably set at a depth with which the base material is partially cut. When the resin sheet laminate of the present invention is produced by this method, a concave portion not penetrating the base material is carved at almost the same position of the base material as a position of cutting of the phosphor-containing resin sheet 2 virtually in most cases. In this case, the concave portion is often formed in the form of a continuous groove or an intermittent groove, but the concave portion may be a break partially penetrating the base material as long as the base material is not split.

The resin sheet laminate of the present invention can be suitably produced by any of the above-mentioned methods; however, a particularly suitable method is a method in which the phosphor-containing resin sheet 2 is formed and then machined into subdivisions. In this method, it is easy to obtain a uniform phosphor-containing resin sheet 2 since there is no possibility of sheet damage due to the contact of the phosphor-containing resin sheet 2 with a resist, a chemical solution or a printing plate material.

The method for producing a resin sheet laminate of the present invention will be described in more detail. The following description is just an example, and the method for producing a resin sheet laminate is not limited to the example. First, a solution in which a phosphor is dispersed in a resin (hereinafter, referred to as a “sheet solution”) is prepared as an application solution for forming a phosphor-containing resin sheet. The sheet solution can be prepared by mixing a phosphor with a resin in an appropriate solvent. In the case of using an addition reaction type silicone resin, since a curing reaction may occur at room temperature if a compound containing an alkenyl group coupled with a silicon atom is mixed with a compound containing a hydrogen atom coupled with a silicon atom, a retardant for a hydrosilylation reaction such as an acetylene compound can also be further mixed in the sheet solution to extend the pot life. It is also possible to mix a dispersant or a leveling agent for stabilizing a coating film as an additive, or an adhesion aid such as a silane coupling agent as a modifier of a sheet surface in the sheet solution. Also, inorganic particles such as silicone fine particles can be mixed in the sheet solution as an anti-settling agent for a phosphor.

The solvent is not particularly limited as long as it can adjust the viscosity of a fluid resin. Examples of the solvent include toluene, methyl ethyl ketone, methyl isobutyl ketone, hexane, acetone, and the like.

These components are blended so as to have a predetermined composition, and then the resulting mixture is uniformly mixed/dispersed with a mixer/kneader such as a homogenizer, a rotation-revolution mixer, a 3roll mill, a ball mill, a planetary ball mill or a beads mill to obtain a sheet solution. After mixing/dispersing or in the process of mixing/dispersing, defoaming is also preferably performed in a vacuum or under a reduced pressure.

Next, the sheet solution is applied onto a base material and dried. The sheet solution can be applied by using a reverse roll coater, a blade coater, a slit die coater, a direct gravure coater, an offset gravure coater, a kiss coater, screen printing; a natural roll coater, an air knife coater, a roll blade coater, a baribar roll blade coater, a two stream coater, a rod coater, a wire bar coater, a coating applicator, a dip coater, a curtain coater, a spin coater, a knife coater or the like. In order to achieve uniformity of the thickness of the sheet, the sheet solution is preferably applied with a slit die coater. Further, the phosphor-containing resin sheet of the present invention can also be produced by using a printing method such as screen printing, gravure printing, or planographic printing. Particularly, screen printing is preferably used.

A sheet can be dried by using a common heating apparatus such as a hot air drier or an infrared drier. A common heating apparatus such as a hot air drier or an infrared drier is used for thermally curing the sheet. In this case, thermal curing is usually performed under the conditions of a temperature of 40 to 250° C. and a heating time of 1 minute to 5 hours, and preferably under the conditions of a temperature of 100° C. to 200° C. and a heating time of 2 minutes to 3 hours.

As described above, the phosphor-containing resin sheet 2 formed on the base material can be divided into subdivisions of a predetermined shape by the method described above.

Further, when it is desired to obtain a divided shape of the phosphor-containing resin sheet 2 other than a simple rectangle as shown in FIGS. 2 and 3, a photomask or screen plate with a desired pattern has only to be prepared. In the case of machining a uniform phosphor-containing resin sheet 2 into a subdivision shape later, the phosphor resin layer needs to be machined by laser beam machining or the like before or after dividing the phosphor resin layer into individual subdivisions.

(Bonding of Phosphor-Containing Resin Sheet 2 to Semiconductor Light-Emitting Element)

Next, an exemplary method for producing a semiconductor light-emitting element with a phosphor-containing resin sheet by use of the resin sheet laminate of the present invention will be described. Since the resin sheet laminate according to an embodiment of the present invention has a resin sheet containing a phosphor and a resin on a long base material and subdivisions of the resin sheet are repeatedly arranged in a lengthwise direction of the long base material, the resin sheet laminate can be suitably used for a method for producing a semiconductor light-emitting element with a phosphor-containing resin sheet including at least:

(A) an alignment step of opposing one subdivision of the phosphor-containing resin sheet on the long base material to an emission surface of one semiconductor light-emitting element, and

(B) an adhering step of adhering the one subdivision of the phosphor-containing resin sheet to the emission surface of the one semiconductor light-emitting element by pressing with a pressure tool, wherein

adhesion of the phosphor-containing resin sheet to the semiconductor light-emitting element is sequentially performed by performing the steps (A) and (B) repeatedly.

Herein, “performing the steps (A) and (B) repeatedly” refers to repeatedly perform the operation of performing the steps (A) and (B) on a pair of an n-th subdivision of the phosphor-containing resin sheet on a long base material and an emission surface of an n-th semiconductor light-emitting element, and then performing the steps (A) and (B) on a pair of a (n+1)th subdivision and an emission surface of a (n+1)th semiconductor light-emitting element. Herein, n is an integer of 1 or more.

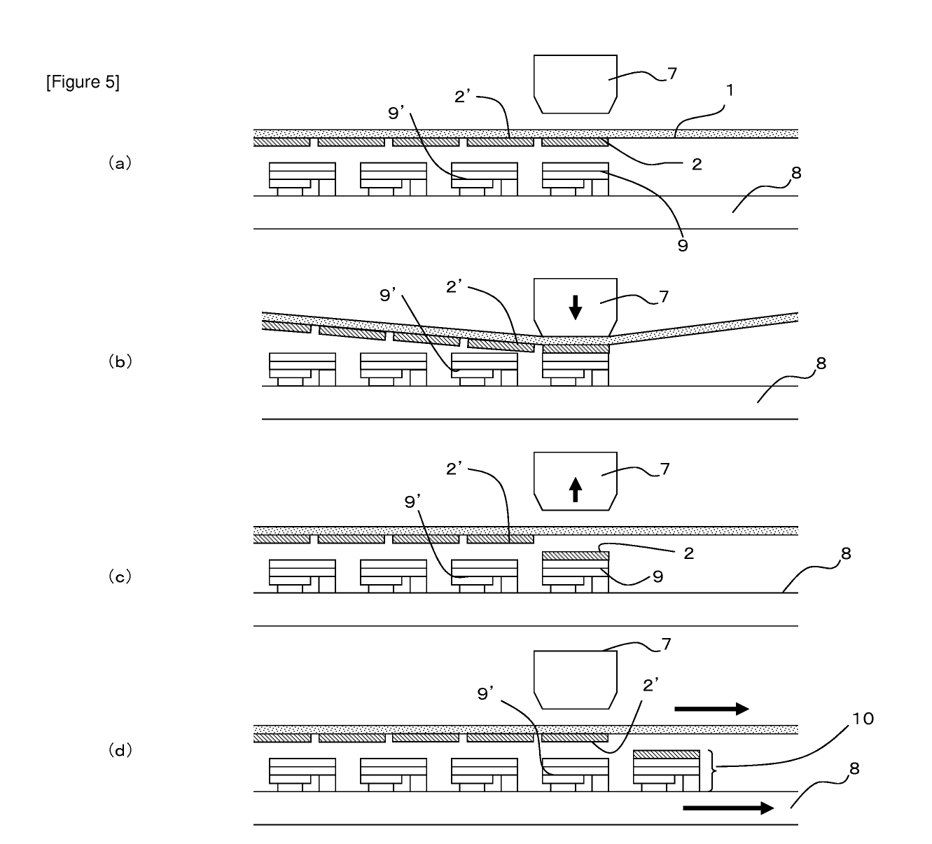

FIG. 5 shows a first example of a method for producing a semiconductor light-emitting element with a phosphor-containing resin sheet 2 using the resin sheet laminate of the present invention. Subdivisions of the phosphor-containing resin sheet 2 are arrayed on the long base material 1 and semiconductor light-emitting elements 9 are arranged at locations on a moving stage 8 opposed to these subdivisions. The first example pertains to a method for producing a semiconductor light-emitting element with a phosphor-containing resin sheet in which the semiconductor light-emitting elements are repeatedly arranged in one direction on a stage on which the adhering step is performed.

As shown in FIG. 5(a), a first subdivision of the phosphor-containing resin sheet 2 and an emission surface of a first semiconductor light-emitting element 9 are aligned with each other so as to be opposed to each other. It is suitable to install an optical alignment system in aligning both of the first subdivision of the phosphor-containing resin sheet and the emission surface of the first semiconductor light-emitting element.

Next, as shown in FIG. 5(b), the phosphor-containing resin sheet 2 is adhered to the semiconductor light-emitting element 9 by pressing from a base material 1 side by use of a pressure tool 7.

Then, as shown in FIG. 5(c), the pressure tool 7 is pulled up to stop pressing. At this time, by properly adjusting an adhesive power between the base material 1 and the phosphor-containing resin sheet 2 and an adhesive power between the phosphor-containing resin sheet 2 and the semiconductor light-emitting element 9 in advance, the base material 1 is peeled off from the phosphor-containing resin sheet 2 in concurrence with pulling up of the pressure tool 7, and only the phosphor-containing resin sheet 2 is left adhered to the semiconductor light-emitting element 9.

Examples of a method of properly adjusting an adhesive power between the base material 1 and the resin sheet include a method of selecting the material of the base material 1, and a method of providing the release layer 4 between the base material 1 and the phosphor-containing resin sheet 2 as shown in FIG. 4(b).

Then, as shown in FIG. 5(d), the resin sheet laminate and the stage holding the semiconductor light-emitting elements arrayed thereon are moved, and a second subdivision (indicated by the reference sign 2′ in the drawing) of the phosphor-containing resin sheet and a second semiconductor light-emitting element 9 (indicated by the reference sign 9′ in the drawing) are opposed to each other and aligned with each other.

When the operations shown in FIG. 5(b) to FIG. 5(d) are thus performed repeatedly, a semiconductor light-emitting element 10 with a phosphor-containing resin sheet 2 can be sequentially produced at a high throughput.

In the first example, the semiconductor light-emitting elements are repeatedly arranged in one direction in advance. A method for producing a semiconductor light-emitting element with a phosphor-containing resin sheet using the resin sheet laminate of the present invention is not necessarily limited to this embodiment, and it is possible to employ an embodiment in which semiconductor light-emitting elements are sent to the stage separately, for example; however, the embodiment of the first example can be mentioned as a more preferred embodiment.

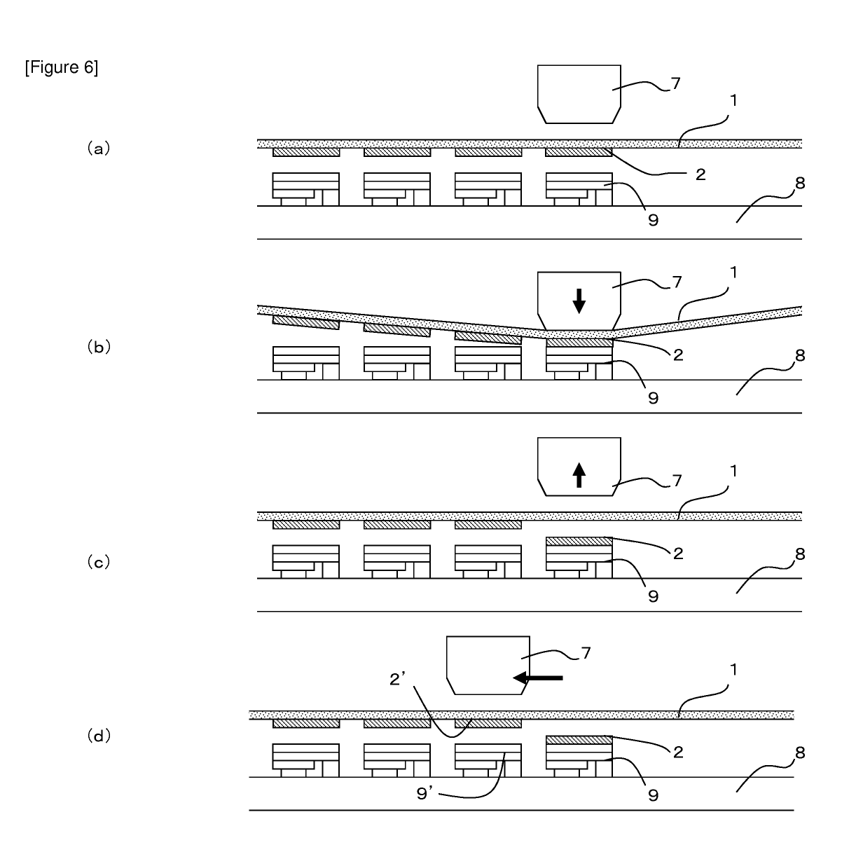

FIG. 6 shows a second example of a method for producing a semiconductor light-emitting element with a phosphor-containing resin sheet 2 using the resin sheet laminate according to an embodiment of the present invention. The second example pertains to a method for producing a semiconductor light-emitting element with a phosphor-containing resin sheet in which an array pitch in the lengthwise direction of the phosphor-containing resin sheet and an array pitch in one direction of the semiconductor light-emitting element are the same.

Here, the phrase “an array pitch of subdivisions of the phosphor-containing resin sheet and an array pitch of the semiconductor light-emitting element are the same” refers to a state in which pitches are identical to each other to such an extent that the phosphor-containing resin sheet does not have to be newly aligned to the semiconductor light-emitting element when the sheet is adhered to the semiconductor light-emitting element.

In the first example, since an array pitch of the subdivisions of the phosphor-containing resin sheet 2 in the resin sheet laminate is different from an array pitch of the semiconductor light-emitting element 9, it is necessary to align each of subdivisions of the phosphor-containing resin sheet 2 with each of semiconductor light-emitting elements 9 one by one. Each of subdivisions of the phosphor-containing resin sheet 2 may be aligned with each of semiconductor light-emitting elements 9 one by one also in the second example, but alignment for every subdivision can be omitted since a plurality of subdivisions of the phosphor-containing resin sheet 2 can be previously aligned with a plurality of semiconductor light-emitting elements 9.

Accordingly, a preferred embodiment in the second example pertains to a method for producing a semiconductor light-emitting element with a phosphor-containing resin sheet, wherein

the step (A) is (C) an alignment step of opposing a plurality of subdivisions of the phosphor-containing resin sheet to a plurality of emission surfaces of the semiconductor light-emitting elements at a time,

the step (B) is (D) an adhering step of adhering sequentially the subdivisions of the phosphor-containing resin sheet to the emission surfaces of the semiconductor light-emitting elements by pressing with a pressure tool, and

adhesion of the phosphor-containing resin sheet to the semiconductor light-emitting element is sequentially performed by performing the steps (C) and (D) repeatedly.

As shown in FIG. 6(a), the subdivisions of the phosphor-containing resin sheet 2 are arrayed on the base material 1 and the semiconductor light-emitting elements 9 are arranged at locations on the stage 8 opposed to these subdivisions, and therefore the phosphor-containing resin sheet 2 on the base material 1 and the semiconductor light-emitting element 9 on the stage 8 are arrayed at the same pitch and a plurality of subdivisions of the phosphor-containing resin sheet 2 and a plurality of semiconductor light-emitting elements 9 are simultaneously aligned with each other and opposed to each other.

As shown in FIG. 6(b), the first subdivision of the phosphor-containing resin sheet 2 is adhered to the first semiconductor light-emitting element 9 by pressing from a base material 1 side by use of a pressure tool 7.

Then, as shown in FIG. 6(c), the pressure tool 7 is pulled up to stop pressing. At this time, by properly adjusting an adhesive power between the base material 1 and the phosphor-containing resin sheet 2 and an adhesive power between the phosphor-containing resin sheet 2 and the semiconductor light-emitting element 9 in advance, the base material 1 is peeled off from the phosphor-containing resin sheet 2 in concurrence with pulling up of the pressure tool 7, and only the phosphor-containing resin sheet 2 is left adhered to the semiconductor light-emitting element 9.

Subsequently, as shown in FIG. 6(d), the pressure tool 7 moves to a position above a second subdivision of the phosphor-containing resin sheet 2 and a second semiconductor light-emitting element 9.

Thereafter, the operations shown in FIG. 6(b) to FIG. 6(d) are performed repeatedly, whereby a semiconductor light-emitting element 10 with a phosphor-containing resin sheet can be sequentially produced at a high throughput.

A range in which an array pitch of subdivisions of the phosphor-containing resin sheet and an array pitch of the semiconductor light-emitting elements are the same does not have to extend throughout the long base material. If there are several to more than a dozen portions where the respective pitches are the same, the above-mentioned second example can be performed for the portions, and a takt time can be shortened. The step (D) may be newly performed at a location where the pitch starts to deviate.

Further, an example of a method of moving the pressure tool is shown in FIG. 6(d), but a positional relationship between the pressure tool and a set of a resin sheet laminate and a stage aligned with each other has only to be a relationship of relative displacement. Accordingly, the pressure tool may remain stationary while the set of a resin sheet laminate and a stage aligned with each other is moved, or both of them may be moved.

Further, when the array pitch of subdivisions of the phosphor-containing resin sheet and the array pitch of the semiconductor light-emitting elements are the same, a plurality of subdivisions of the phosphor-containing resin sheet and a plurality of semiconductor light-emitting elements can be simultaneously adhered to each other by pressing the resin sheet and the elements. That is, in the step (D), when two or more subdivisions of a plurality of opposed subdivisions of the phosphor-containing resin sheet are simultaneously pressed, the two or more subdivisions of the phosphor-containing resin sheet can be adhered to two or more emission surfaces of the semiconductor light-emitting elements.

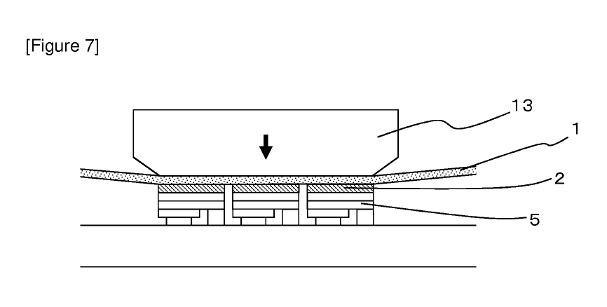

A variation of the second example is a method in which, by pressing simultaneously two or more subdivisions of a plurality of opposed subdivisions of the phosphor-containing resin sheet in the step (D), the two or more subdivisions of the phosphor-containing resin sheet are adhered to two or more emission surfaces of the semiconductor light-emitting elements. FIG. 7 shows an example in which three subdivisions of the phosphor-containing resin sheet 2 are simultaneously adhered to three semiconductor light-emitting elements 9 by pressing by use of a pressure tool 13 of batch process. In FIG. 7, the number of the subdivisions of the phosphor-containing resin sheet and the number of the semiconductor light-emitting elements simultaneously pressed/adhered are respectively 3; however, the number of the subdivisions and the elements are not limited.

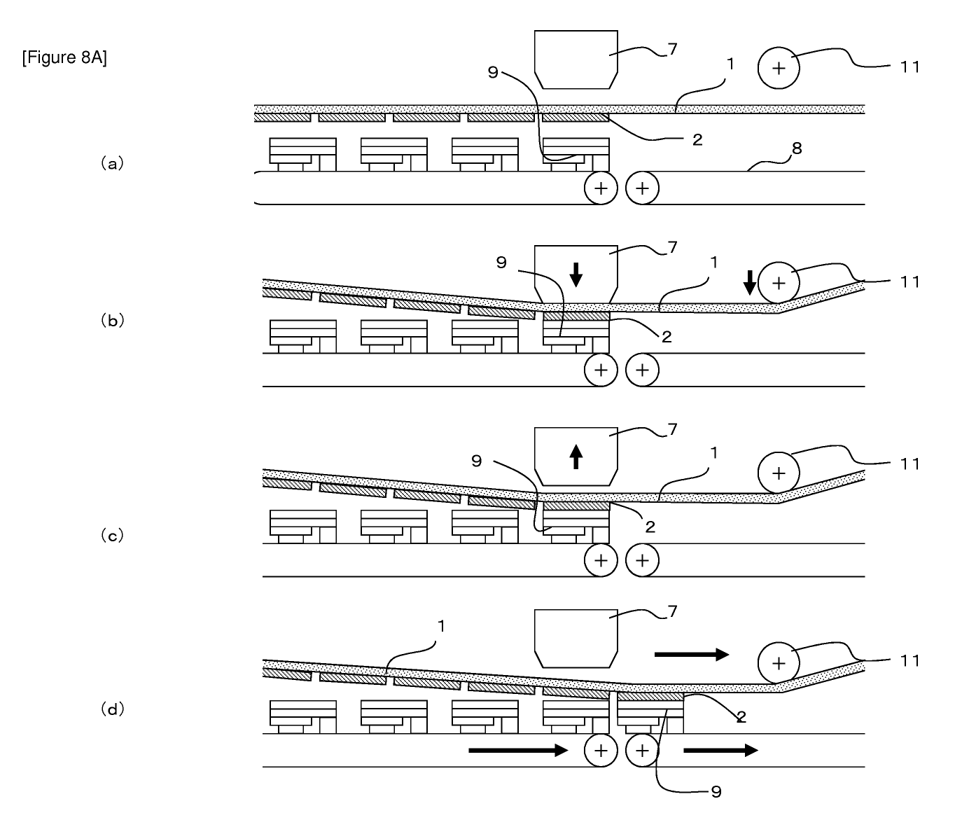

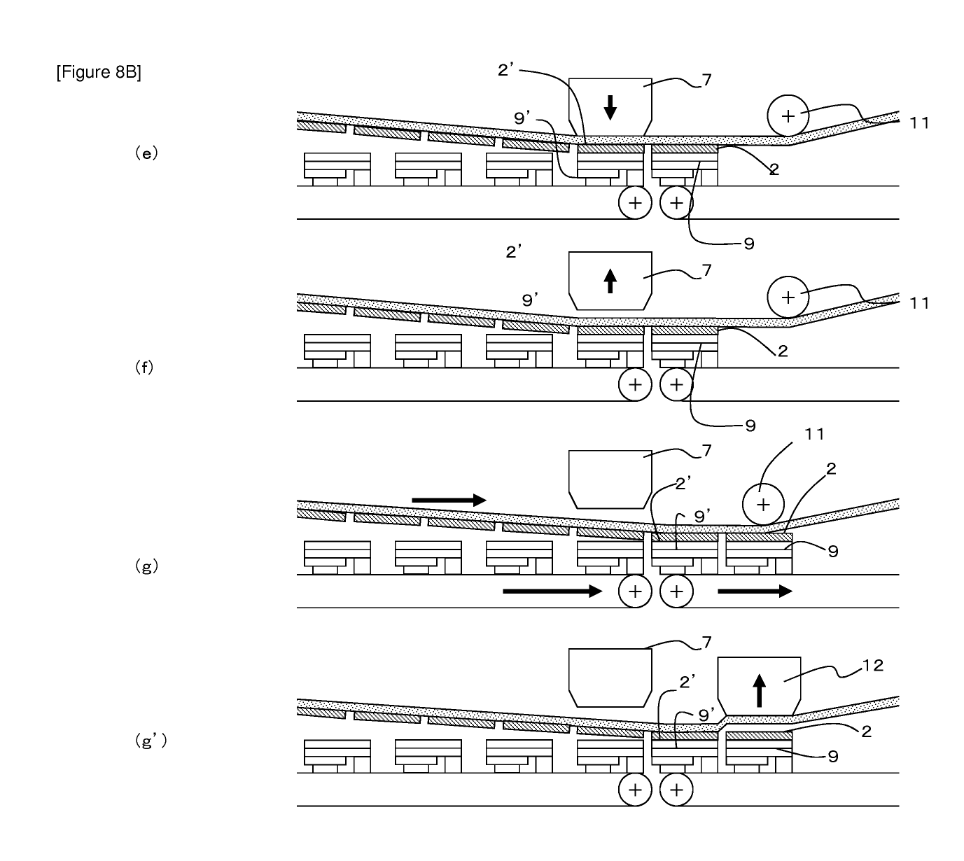

FIG. 8 (FIG. 8A to FIG. 8B) shows a third example of a method for producing a semiconductor light-emitting element with a phosphor-containing resin sheet 2 using the resin sheet laminate of an embodiment of the present invention, which is an example of a case in which an adhesive power between the base material 1 and the phosphor-containing resin sheet 2 is relatively high and a peeling tool is required in addition to the pressure tool 7.

In FIG. 8(a), the subdivisions of the phosphor-containing resin sheet 2 are arrayed on the base material 1 and the semiconductor light-emitting elements 9 are arranged at locations on the moving stage 8 opposed to the subdivisions of the phosphor-containing resin sheet 2. A pressure tool 7 and a peeling roller 11 are placed on a base material 1 side of the resin sheet laminate.

As shown in FIG. 8(b), the phosphor-containing resin sheet 2 is adhered to the semiconductor light-emitting element 9 by pressing from the base material 1 side by use of the pressure tool 7. The peeling roller 11 descends to the same height as that of the pressure tool 7 to be brought into contact with the base material 1 in concurrence with the adhesion or after adhesion.

As shown in FIG. 8(c), even when the pressure tool 7 is raised to release pressing, the base material 1 does not peel off by itself from the phosphor-containing resin sheet 2 when an adhesive power between the base material 1 and the phosphor-containing resin sheet 2 is relatively high.

As shown in FIG. 8(d), the base material 1, the phosphor-containing resin sheet 2 and the semiconductor light-emitting element 9 are sent rightward in the drawing in a state of being adhered to one another.

As shown in FIG. 8(e) and FIG. 8(f), a second subdivision of the phosphor-containing resin sheet 2 is adhered to a second semiconductor light-emitting element 9 by the pressure tool 7, and the resin sheet laminate and the semiconductor light-emitting element are further sent rightward in the drawing.

In FIG. 8(g), the base material 1 is pulled up starting from an end of the semiconductor light-emitting element 9 upon arrival of the first subdivision of the phosphor-containing resin sheet 2 and the first semiconductor light-emitting element 9 at the peeling roller 11, and the base material 1 is peeled off from the subdivision of the phosphor-containing resin sheet 2.

As a tool for peeling off the base material 1 from the phosphor-containing resin sheet 2, a vacuum adsorption-peeling tool 12 which pulls up the base material 1 by adsorption as shown in FIG. 8(g′) may be employed other than the peeling roller 11 as shown in FIGS. 8(a) to 8(g).

Further, in FIG. 8, the second subdivision of the phosphor-containing resin sheet 2 is aligned with the second semiconductor light-emitting element 9 so that the carrying speed of the semiconductor light-emitting element can be varied between before and after the adhesion. The reason for this is as follows: since an array pitch of the subdivisions of the phosphor-containing resin sheet 2 on the base material 1 is different from an array pitch of the semiconductor light-emitting elements 9, the second subdivision of the phosphor-containing resin sheet 2 cannot be aligned with the second semiconductor light-emitting element 9 if both of the carrying speeds of the base material 1 and the semiconductor light-emitting element 9 are constant between before and after the first subdivision of the phosphor-containing resin sheet 2 is adhered to the first semiconductor light-emitting element 9. When the array pitch of subdivisions of the phosphor-containing resin sheet 2 and the array pitch of the semiconductor light-emitting elements 9 are the same, such adjustment is unnecessary.

There may be cases where air bubbles enter an adhering surface depending on flexibility of the phosphor-containing resin sheet or the base material when the phosphor-containing resin sheet is adhered to the emission surface of the semiconductor light-emitting element. Once air bubbles enter, it is difficult to eliminate them, and therefore emission from the semiconductor light-emitting element is scattered and optical characteristics are significantly impaired. Accordingly, it is important to avoid entering of air bubbles upon adhesion. As a method therefor, there is an effective method in which a part of the surface of the subdivision is pressed first without pressing simultaneously and evenly the whole surface and then other regions are pressed in adhering the phosphor-containing resin sheet to the semiconductor light-emitting element.

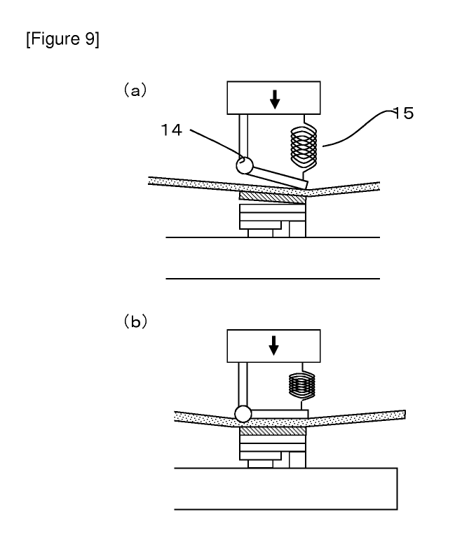

FIG. 9 shows drawings schematically showing an example of a structure of a pressure tool for preventing entering of air bubbles. The pressure tool has a movable portion 14 such as a hinge and an elastic body structure 15 such as a spring in the inside. When pressing is started, a side of the tool which has the elastic body structure 15 starts pressing the resin sheet laminate first, and the elastic body structure 15 contracts and the movable portion 14 is simultaneously folded by pressing the pressure tool down to press the resin sheet laminate from the end of the elastic body structure 15 toward the opposite end, and hence air is pushed out from right to left in the drawing to prevent entering of air bubbles.

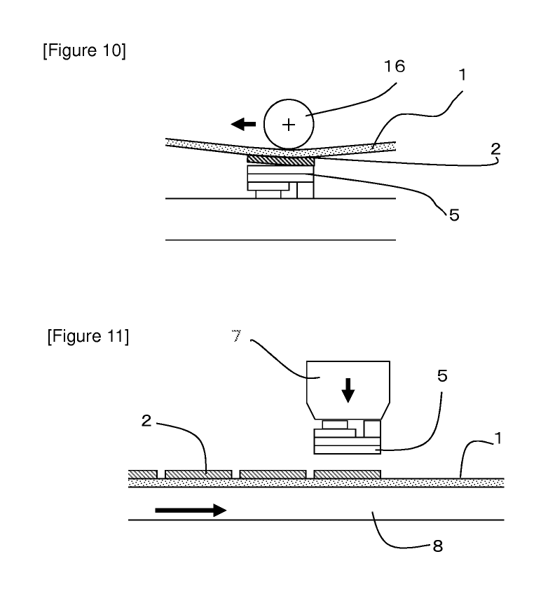

FIG. 10 shows a second example of a pressure tool for preventing entering of air bubbles. A subdivision of the phosphor-containing resin sheet 2 is pressed from the base material 1 side by a pressure roller 16 and adhered to an emission surface of the semiconductor light-emitting element 9. The pressure roller 16 presses the subdivision of the phosphor-containing resin sheet 2 from the right side toward the left side in the drawing, and thereby, air at an adhering interface is squeezed out in succession to enable prevention of entering of air bubbles.

Structures of pressure tools for preventing entering of air bubbles as shown in FIG. 9 and FIG. 10 are applicable to any of production methods described in reference to FIGS. 5 to 8. Further, both of FIG. 9 and FIG. 10 show examples of the case in which the pressure tool presses the phosphor-containing resin sheet 2 from the base material side; however, the structure is also applicable to a case in which the pressure tool performs pressing from a side of the semiconductor light-emitting element, as described below. That is, the pressure tool preferably presses a part of the subdivision to be pressed first and presses a different region thereafter.

All of the production methods shown in FIGS. 5 to 10 are methods in which the resin sheet laminate of the present invention is arranged with the phosphor-containing resin sheet 2 directed downward, the semiconductor light-emitting elements 9 are arrayed on the stage below the resin sheet laminate with the emission surface of the element 9 directed upward, and adhesion is performed by pressing from the base material 1 side of the resin sheet laminate with the pressure tool 7; however, the order of arrangement of the resin sheet laminate, the semiconductor light-emitting element and the pressure tool in the vertical direction is not necessarily limited to this order, and the resin sheet laminate may be located in a lower portion and the semiconductor light-emitting element may be located in an upper portion, or the pressure tool may perform pressing from the semiconductor light-emitting element side in the adhering step.

An example is shown in FIG. 11. This example pertains to a method including:

(E) a step of arranging the resin sheet laminate on the stage with the subdivision of the resin sheet directed upward,

(F) a step of opposing the emission surface of the semiconductor light-emitting element to the subdivision of the resin sheet by directing the emission surface downward, and

(G) a step of adhering the subdivision of the phosphor-containing resin sheet to the emission surface of the semiconductor light-emitting element by performing pressing from the semiconductor light-emitting element side.

The resin sheet laminate is arranged on the stage 8 with the base material 1 placed on the stage and the subdivision of the phosphor-containing resin sheet 2 placed thereon. The semiconductor light-emitting element 9 is arranged above the subdivision of the phosphor-containing resin sheet 2, and the semiconductor light-emitting element 9 is pressed from above by a pressure tool 7 holding the semiconductor light-emitting element by adsorption and adhered to the subdivision of the phosphor-containing resin sheet 2.

In all the cases shown in FIGS. 5 to 10, when the subdivision of the phosphor-containing resin sheet 2 has an adhesive property or tackiness or when a resin layer having an adhesive property or tackiness is laminated on the subdivision of the phosphor-containing resin sheet 2, the phosphor-containing resin sheet 2 and the semiconductor light-emitting element 9 are adhered to each other by pressing with a pressure tool. When the phosphor-containing resin sheet 2 has thermal adhesiveness or when a resin having thermal adhesiveness is laminated on the phosphor-containing resin sheet 2, the subdivision of the phosphor-containing resin sheet 2 and the semiconductor light-emitting element 9 are adhered to each other by applying heat during pressing with a pressure tool.

As a method of applying heat during pressing, a method of providing the pressure tool 7 with a heating function, a method of providing the stage 8 holding the semiconductor light-emitting elements 9 arrayed thereon with a heating function to heat the semiconductor light-emitting element 9, a method of using radiation heat such as infrared rays, and a method of raising the ambient temperature of a location to be pressed are applicable.

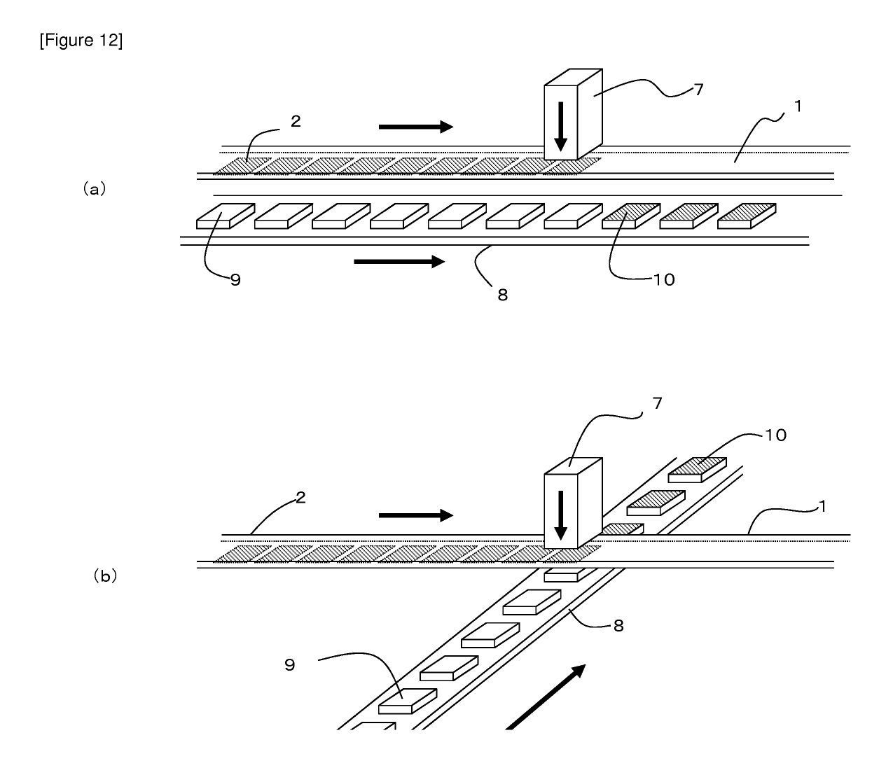

In the production methods in FIG. 5 and FIGS. 7 to 11, when the resin sheet laminate of the present invention and the semiconductor light-emitting element relatively move, the subdivisions of the phosphor-containing resin sheet 2 are sequentially adhered to the semiconductor light-emitting elements 9. With respect to directions to relatively move the resin sheet and the light-emitting element, for example, as shown in FIG. 12(a), a lengthwise direction of the resin sheet laminate composed of the base material 1 and the subdivisions of the phosphor-containing resin sheet 2 and a direction of the stage holding the semiconductor light-emitting elements arrayed thereon are commonly made parallel to each other, but these two directions do not necessarily have to be parallel, and they may be orthogonal as shown in FIG. 12(b). That is, “one direction” when the semiconductor light-emitting elements are repeatedly arranged in one direction on a stage on which the adhering step is performed does not have to be identical to the lengthwise direction of the phosphor-containing resin sheet.

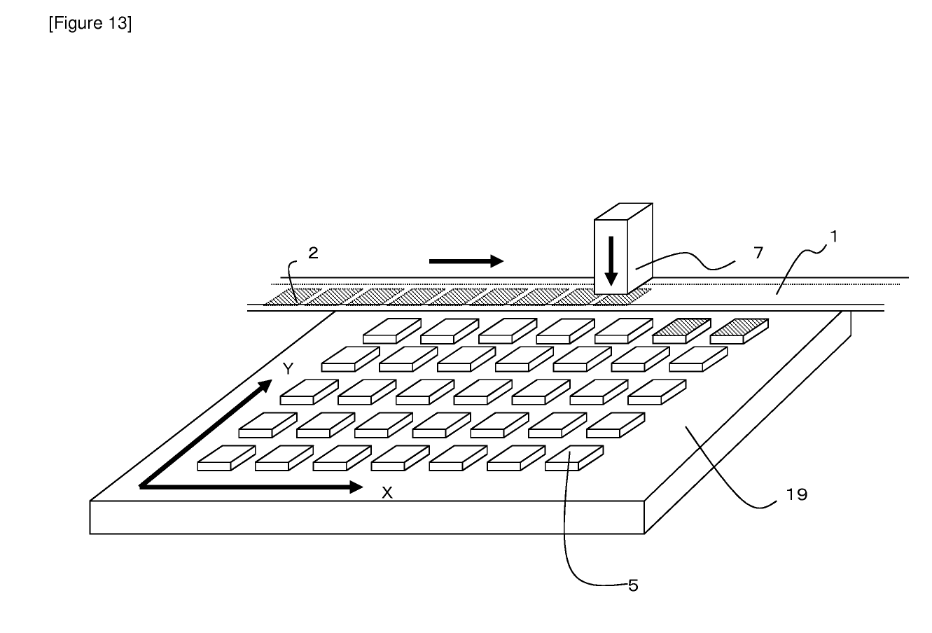

Further, FIG. 13 shows an example of a case in which the semiconductor light-emitting elements 9 are arrayed two-dimensionally on a stage 19 which moves in X and Y directions. The phosphor-containing resin sheet 2 is sequentially adhered to one line of array of the semiconductor light-emitting elements arranged two-dimensionally while alternately moving the resin sheet laminate and the X-Y moving stage 19 in an X direction, and after completion of adhesion of the phosphor-containing resin sheet 2 to the one line of the semiconductor light-emitting elements, the X-Y moving stage is moved in a Y direction by one line of the semiconductor light-emitting elements, and the phosphor-containing resin sheet 2 is sequentially adhered to a second line of array of the semiconductor light-emitting elements, and thereby, the phosphor-containing resin sheet 2 can be sequentially adhered to the semiconductor light-emitting elements arranged two-dimensionally.

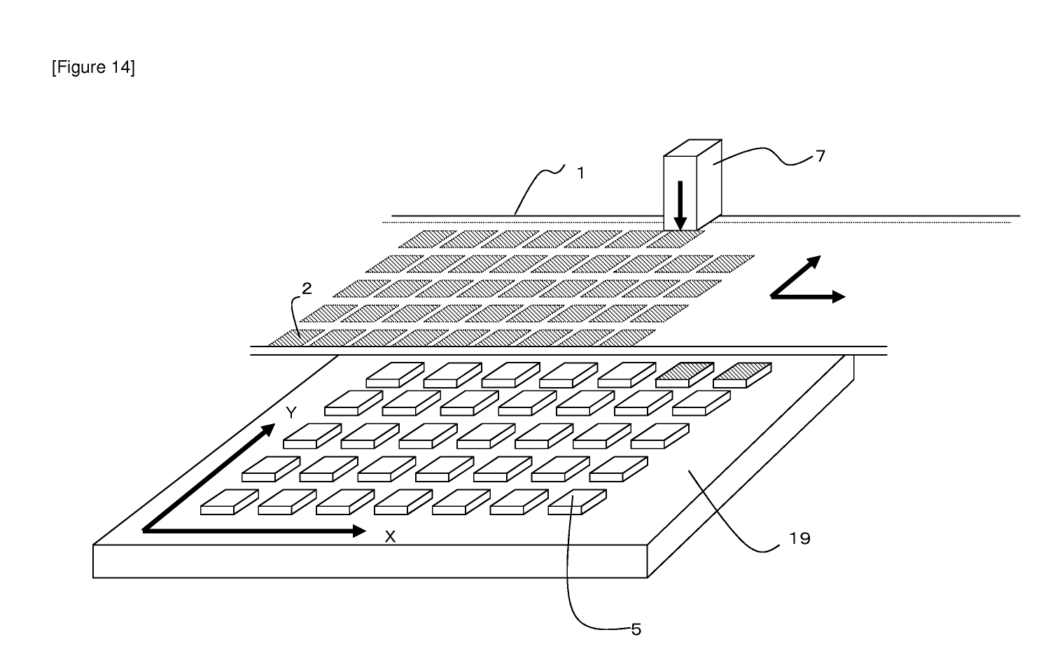

The phosphor-containing resin sheet 2 on the resin sheet laminate may also be arranged two-dimensionally, and the resin sheet laminate and the semiconductor light-emitting elements may be respectively arranged two-dimensionally as shown in FIG. 14, and relatively moved two-dimensionally to sequentially adhere the phosphor-containing resin sheet 2 to the semiconductor light-emitting elements 9. That is, when subdivisions of the resin sheet are repeatedly arranged in the lengthwise direction of the long base material, the subdivisions are inevitably also repeatedly arranged in a direction other than the lengthwise direction.

Similarly, when the semiconductor light-emitting elements are repeatedly arranged in one direction on a stage on which the adhering step is performed, the semiconductor light-emitting elements are inevitably also repeatedly arranged in a direction other than the one direction. Further, for example, when it is possible to align the phosphor-containing resin sheet with the semiconductor light-emitting elements in a plurality of lines in the Y direction in FIG. 14, two or more lines of the resin sheet laminate and the semiconductor light-emitting elements may be simultaneously adhered to each other.

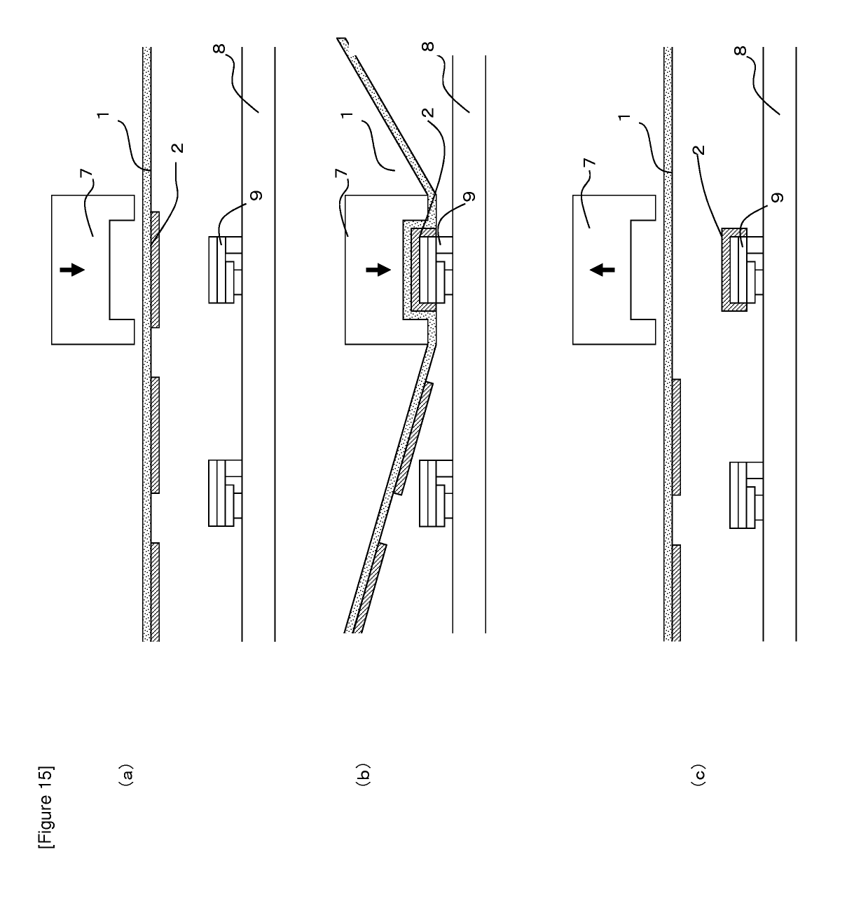

In the production methods in FIG. 5 and FIGS. 7 to 11, all the phosphor-containing resin sheets 2 of the resin sheet laminate of the present invention are bonded in a planar form to an upper emission surface of the semiconductor light-emitting element; however, all of these production methods can be applied to a method in which the phosphor-containing resin sheet 2 is bonded also to the side surface of the semiconductor light-emitting element. FIG. 15 shows an example thereof.

As shown in FIG. 15(a), the resin sheet laminate of the present invention is arranged with the phosphor-containing resin sheet 2 directed downward above the semiconductor light-emitting element 9 arranged on the stage 8, and a pressure tool 7 having a concave portion is arranged on the base material side. The phosphor-containing resin sheet 2 is designed to have a size larger than that of an upper emission surface of the semiconductor light-emitting element 9.

As shown in FIG. 15(b), the resin sheet laminate is pressed against the semiconductor light-emitting element 9 from the base material side by the pressure tool 7 having a concave portion. At this time, the semiconductor light-emitting element 9 is surrounded by the concave portion of the pressure tool 7, and the resin sheet laminate is pressed against a top surface and a part of a side surface of the semiconductor light-emitting element 9.

As shown in FIG. 15(c), a semiconductor light-emitting element 9 having an entire top surface and a part of a side surface covered with the phosphor-containing resin sheet 2 is produced by moving the pressure tool 7 upward and separating it from the resin sheet laminate. When the semiconductor light-emitting element 9 has a radiation direction of emission also at its side surface, the side surface of the semiconductor light-emitting element 9 should be covered with the phosphor-containing resin sheet 2 as described above. In accordance with the present invention, it is possible to easily cover the side surface.

### REFERENCE SIGNS LIST

1 Base material
2, 2′ Phosphor-containing resin sheet
3 Conveyance hole
4 Release layer
5 Adhesion layer
6 Groove on base material
7 Pressure tool
8 Moving stage
9, 9′ Semiconductor light-emitting element
10 Semiconductor light-emitting element with phosphor-containing resin sheet
11 Peeling roller
12 Adsorption-peeling tool
13 Pressure tool of batch process
14 Movable portion
15 Elastic body structure
16 Pressure roller
19 Stage

1. A resin sheet laminate having a resin sheet containing a phosphor and a resin on or over a long base material, wherein subdivisions of the resin sheet are repeatedly arranged in a lengthwise direction of the long base material.

2. The resin sheet laminate according to claim 1, wherein the thickness of the resin sheet is 200 μm or less.

3. The resin sheet laminate according to claim 1, wherein a plurality of lines of the resin sheets are arranged in a widthwise direction of the long base material.

4. The resin sheet laminate according to claim 1, wherein conveyance holes are formed in the long base material.

5. The resin sheet laminate according to claim 1, wherein the resin sheet laminate has a release layer between the long base material and the resin sheet.

6. The resin sheet laminate according to claim 1, wherein an adhesion layer or an adhesive layer is provided on a surface of the resin sheet opposite to the long base material.

7. The resin sheet laminate according to claim 1, wherein the resin sheet has thermal adhesiveness.

8. The resin sheet laminate according to claim 1, wherein a groove is provided at a position substantially conforming to the subdivision of the resin sheet in the long base material.

9. The resin sheet laminate according to claim 1, wherein the resin sheet is bonded to an emission surface of an LED.

10. A method for producing a semiconductor light-emitting element with a phosphor-containing resin sheet using the resin sheet laminate according to claim 1, comprising at least:
(A) an alignment step of opposing one subdivision of the phosphor-containing resin sheet on the long base material to an emission surface of one semiconductor light-emitting element, and
(B) an adhering step of adhering the one subdivision of the phosphor-containing resin sheet to the emission surface of the one semiconductor light-emitting element by pressing with a pressure tool, wherein
adhesion of the phosphor-containing resin sheet to the semiconductor light-emitting element is sequentially performed by performing the steps (A) and (B) repeatedly.

11. The method for producing a semiconductor light-emitting element with a phosphor-containing resin sheet according to claim 10, wherein the semiconductor light-emitting elements are repeatedly arranged in one direction on a stage on which the adhering step is performed.

12. The method for producing a semiconductor light-emitting element with a phosphor-containing resin sheet according to claim 11, wherein an array pitch in a lengthwise direction of the phosphor-containing resin sheet and an array pitch in one direction of the semiconductor light-emitting element are the same.

13. The method for producing a semiconductor light-emitting element with a phosphor-containing resin sheet according to claim 12, wherein
the step (A) is (C) an alignment step of opposing a plurality of subdivisions of the phosphor-containing resin sheet to a plurality of emission surfaces of the semiconductor light-emitting elements at a time,
the step (B) is (D) an adhering step of adhering sequentially the subdivisions of the phosphor-containing resin sheet to the emission surfaces of the semiconductor light-emitting elements by pressing with a pressure tool, and
adhesion of the phosphor-containing resin sheet to the semiconductor light-emitting element is sequentially performed by performing the steps (C) and (D) repeatedly.

14. The method for producing a semiconductor light-emitting element with a phosphor-containing resin sheet according to claim 13, wherein by pressing simultaneously two or more subdivisions of the plurality of opposed subdivisions of the phosphor-containing resin sheet in the step (D), the two or more subdivisions of the phosphor-containing resin sheet are adhered to two or more emission surfaces of the semiconductor light-emitting elements.

15. The method for producing a semiconductor light-emitting element with a phosphor-containing resin sheet according to claim 10, wherein the pressure tool presses the phosphor-containing resin sheet from the base material side in the adhering step.

16. The method for producing a semiconductor light-emitting element with a phosphor-containing resin sheet according to claim 10, wherein the pressure tool performs pressing from the semiconductor light-emitting element side in the adhering step.

17. The method for producing a semiconductor light-emitting element with a phosphor-containing resin sheet according to claim 10, wherein the base material is peeled off by using a peeling tool different from the pressure tool after the subdivision of the phosphor-containing resin sheet is adhered to the emission surface of the semiconductor light-emitting element.

18. The method for producing a semiconductor light-emitting element with a phosphor-containing resin sheet according to claim 10, wherein the pressure tool presses a part of the subdivision to be pressed first and presses a different region thereafter in the adhering step.

19. The method for producing a semiconductor light-emitting element with a phosphor-containing resin sheet according to claim 17, wherein the pressure tool is a pressure roller.

20. The method for producing a semiconductor light-emitting element with a phosphor-containing resin sheet according to claim 10, wherein heating is performed together with pressing in the adhering step.
